(19) United States
(12) Patent Application Publication
(10) Pub. No.: US 2025/0287752 A1
(43) Pub. Date: Sep. 11, 2025

(54) METHOD FOR MANUFACTURING LED DISPLAY

(71) Applicant: Japan Display Inc., Tokyo (JP)

(72) Inventor: Kazuyuki YAMADA, Tokyo (JP)

(21) Appl. No.: 19/046,723

(22) Filed: Feb. 6, 2025

(30) Foreign Application Priority Data
Mar. 11, 2024 (JP) 2024-037241

(51) Int. Cl. H10H 29/01; H01L 25/075

(52) U.S. Cl. CPC H10H 29/036; H01L 25/0753

(57) ABSTRACT

A method for manufacturing an LED display includes a dicing step for dicing a plurality of circuit boards from a multi-sided board having the plurality of circuit boards formed within its surface, a first arrangement step for arranging the plurality of circuit boards on a carrier board, a second arrangement step for arranging the carrier board on a mounting stage, and a mounting step for mounting a plurality of LED chips on the plurality of circuit boards on the mounting stage.

### CROSS-REFERENCE TO RELATED APPLICATIONS

This application claims the benefit of priority to Japanese Patent Application No. 2024-037241, filed on Mar. 11, 2024, the entire contents of which are incorporated herein by reference.

### FIELD

An embodiment of the present invention relates to a method for manufacturing an LED (Light Emitting Diode) display in which a plurality of LED chips is mounted on a circuit board.

### BACKGROUND

In recent years, an LED display in which a plurality of LED chips is mounted on a circuit board has been developed as a next-generation display device. The LED display has a configuration in which the LED chips is mounted on the circuit board called a backplane. For example, a bonding device disclosed in Japanese laid-open patent publication No. 2019-36719 is used for mounting the LED chips.

The method for manufacturing the LED display includes producing multiple LED displays on a large substrate called a mother glass, and dividing the large substrate by dicing the LED displays at the final stage of the manufacturing process.

An alternative manufacturing method includes dividing a large substrate by dicing circuit boards that form the LED displays, then putting the diced circuit board into a bonding device, mounting the LED chips, and extracting it from the bonding device, and the same process is performed for each circuit board.

### SUMMARY

A method for manufacturing an LED display includes a dicing step for dicing a plurality of circuit boards from a multi-sided board having the plurality of circuit boards formed within its surface, a first arrangement step for arranging the plurality of circuit boards on a carrier board, a second arrangement step for arranging the carrier board on a mounting stage, and a mounting step for mounting a plurality of LED chips on the plurality of circuit boards on the mounting stage.

### BRIEF DESCRIPTION OF DRAWINGS

FIG. 1 is a flowchart showing an LED display according to an embodiment of the present invention.

FIG. 2 is a plan view schematically showing a circuit board constituting an LED display according to an embodiment of the present invention.

FIG. 3 is a plan view schematically showing a carrier board used in a method for manufacturing an LED display according to an embodiment of the present invention.

FIG. 4 is a cross-sectional view of line IV-IV in FIG. 3.

FIG. 5 is a cross-sectional view schematically showing a bonding device used in a method for manufacturing an LED display according to an embodiment of the present invention.

### DESCRIPTION OF EMBODIMENTS

Hereinafter, embodiments of the present invention will be described with reference to the drawings. For clarification of the description, the width, thickness, shape, and the like of each part may be schematically represented in comparison with the actual embodiments, but the drawings are merely examples and do not limit the interpretation of the present invention. In the present specification and the drawings, the same reference signs are given to elements similar to those described above with respect to the above-described drawings, and detailed description thereof may be omitted as appropriate.

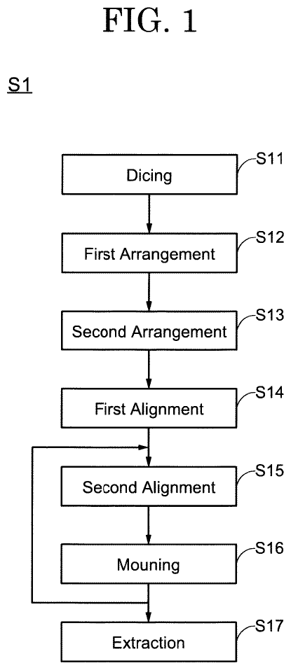

A method for manufacturing an LED display according to an embodiment of the present invention will be described. FIG. 1 is a flowchart schematically showing a process after dicing a circuit board from a large multi-sided board in a manufacturing process of the LED display. As shown in FIG. 1, a method for manufacturing the LED display (S1) includes a dicing step (S11), a first arrangement step (S12), a second arrangement step (S13), a first alignment step (S14), a second alignment step (S15), a mounting step (S16), and an extraction step (S17) in this order.

### Dicing Step

The dicing step (S11) is a step of dicing a plurality of circuit boards from the multi-sided board having the plurality of circuit boards formed within its surface.

A plurality of circuit boards can be obtained by dicing the multi-sided board in which the plurality of circuit boards is formed within its surface with a known slicer. Sizes of the multi-sided board include, but are not limited to, various sizes such as the sixth generation 1500 mm×1800 mm, the eighth generation 2200 mm×2400 mm, and the 10.5 generation 2940 mm×3370 mm. Examples of the material of the multi-sided board include an aluminosilicate glass.

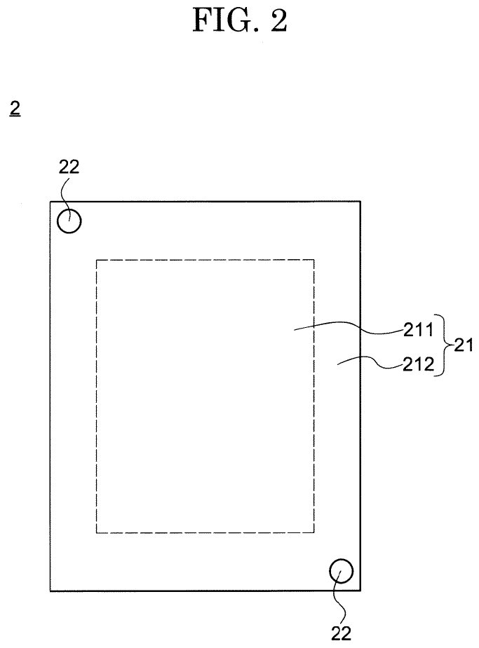

FIG. 2 is a plan view of a diced circuit board 2. As shown in FIG. 2, the circuit board 2 includes a circuit board body 21 including a mounting region 211 on which a pixel array is formed and on which the LED chips is mounted, and a peripheral region 212 surrounding the mounting region 211, and a second alignment mark 22 formed on the peripheral region 212. For example, the circuit board 2 may be a plate-shaped board having a length of 20 mm or more and 60 mm or less and a width of 20 mm or more and 60 mm or less, but is not limited to this.

As shown in FIG. 2, the circuit board 2 has the second alignment mark 22 near each of the opposing vertices of the circuit board body 21. The number and arrangement of the second alignment mark 22 on the circuit board body 21 are not limited to this. In addition, the shape of the second alignment mark 22 is not limited, and examples thereof include a circular shape, an elliptical shape, a polygonal shape, and a cross shape.

Since the circuit board 2 has the second alignment mark 22, the alignment of a bonding head (the LED chips) with respect to the circuit board 2 can be facilitated in the bonding device described later, improving the manufacturing throughput.

### First Arrangement Step

The first arrangement step (S12) is a step of arranging the diced plurality of circuit boards 2 on a carrier board.

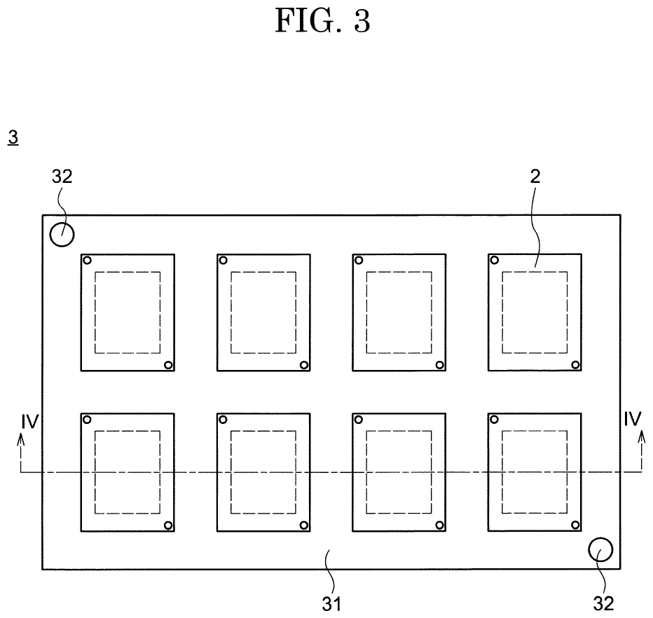

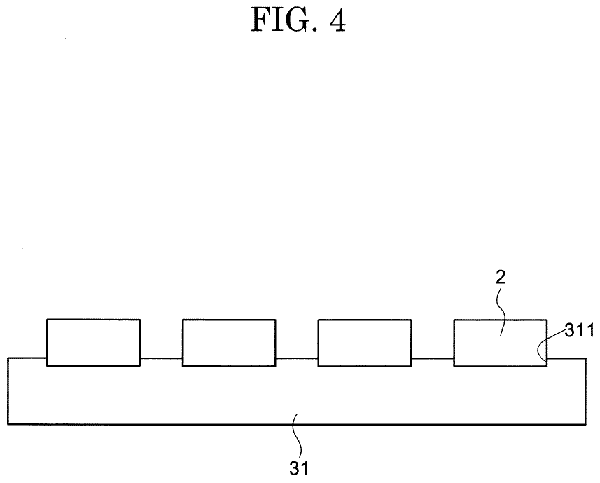

FIG. 3 is a plan view of a carrier board 3. FIG. 4 is a cross-sectional view of line IV-IV in the carrier board 3 of FIG. 3. As shown in FIG. 3, the carrier board 3 has a carrier board body 31 and a first alignment mark 32 formed on the carrier board body 31. The carrier board body 31 is smaller than the multi-sided board. The carrier board body 31 has a rectangular shape in a plan view, and the dimensions of the respective sides include, for example, a plate-like shape having a length of 50 mm or more and 130 mm or less and a width of 140 mm or more and 280 mm or less, but is not limited to this as long as the plate-like shape can be inserted into the bonding device. Even though the multi-sided board itself cannot be put into the bonding device, the carrier board 3 which is smaller than the multi-sided board can be put into the bonding device. Examples of the material of the carrier board body include metals such as aluminum (Al) and stainless steel (SUS).

As shown in FIG. 3, eight circuit board 2 are arranged in two rows and four columns at constant intervals on the carrier board body 31. The number, arrangement, and interval of the circuit board 2 on the carrier board body 31 are not limited to this. By arranging the circuit board 2 on the carrier board 3 periodically, the alignment of the LED chips with respect to the circuit board 2 is facilitated in the bonding device, improving the manufacturing throughput.

As shown in FIG. 3, the carrier board 3 has the first alignment mark 32 near each of the opposing vertices of the carrier board body 31. The number and arrangement of the first alignment mark 32 on the carrier board body 31 are not limited to this. In addition, examples of the shape of the first alignment mark 32 include a circular shape, an elliptical shape, a polygonal shape, and a cross shape. Since the carrier board 3 has the first alignment mark 32, the alignment of the LED chips with respect to the carrier board 3 can be facilitated, improving the manufacturing throughput.

As shown in FIG. 4, a recess portion 311 corresponding to each circuit board 2 is formed in the carrier board body 31. Since the circuit board 2 fits into the recess portion 311, the alignment of the circuit board 2 with respect to the carrier board body 31 can be facilitated. In addition, when the carrier board 3 is put into the bonding device, the aligned circuit board 2 can be prevented from being misaligned. In addition, forming the recess portion 311 may be omitted.

### Second Arrangement Step

The second arranging step (S13) is a step of arranging the carrier board 3 in a mounting stage inside the bonding device while holding the plurality of circuit boards 2. Since the plurality of circuit boards can be put into the bonding device at once, the manufacturing throughput can be improved.

### First Alignment Step

The first alignment step (S14) is a step of aligning the LED chips with respect to the carrier board 3 using the first alignment mark 32 in the carrier board 3 in the bonding device. Inside the bonding device, a camera attached to the bonding head detects the first alignment mark 32, and the mounting stage on which the carrier board 3 is arranged is adjusted in the XYe direction, whereby the reference position of the bonding head can be determined. The first alignment step (S14) is for roughly positioning the LED chips with respect to the circuit board 2 and corresponds to so-called global alignment.

### Second Alignment Step

The second alignment step (S15) is a step of aligning the LED chips with respect to the circuit board 2 using the second alignment mark 22 in the circuit board 2 in the bonding device. The camera attached to the bonding head detects the second alignment mark 22, and the mounting stage is adjusted in the XYθ direction, whereby the position of the bonding head can be determined. The second alignment step (S15) is for precisely positioning the LED chips with respect to the circuit board 2 and corresponds to so-called local alignment.

### Mounting Step

The mounting step (S16) is a step of mounting the LED chips on the mounting region 211 on the circuit board body 21 in the aligned circuit board 2 in the mounting stage of the bonding device.

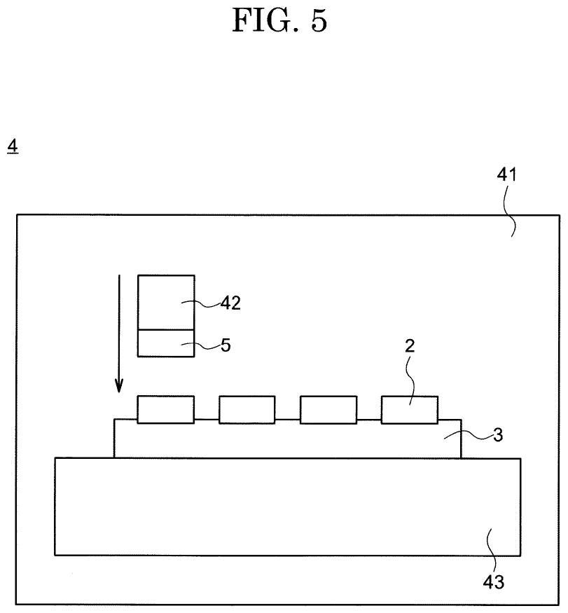

FIG. 5 is a cross-sectional view schematically showing a bonding device. As shown in FIG. 5, a bonding device 4 includes a device body 41, a bonding head 42 arranged inside the device body 41, and a mounting stage 43. The carrier board 3 is arranged on the mounting stage 43 inside the bonding device 4. In addition, a carrier plate 5 on which a plurality of LED chips (not shown) is arranged is attached below the bonding head 42. The bonding head 42 moves from the upper side to the lower side, the LED chips arranged on the carrier plate 5 is bonded to the circuit board 2, and is transferred from the carrier plate 5 by thermocompression bonding or the like, whereby the LEDs chip can be mounted on the circuit board 2. The inside of the device body 41 of the bonding device 4 can be under a nitrogen atmosphere. Furthermore, for the carrier board 3, by forming a fine adhesive layer on the mounting stage 43 and/or vacuum-suctioning via the mounting stage 43, the carrier board 3 can be fixed on the mounting stage 43.

When the mounting of the LED chips are completed for one circuit board 2, the second alignment step (S15) and the mounting step (S16) are performed for the subsequent circuit board 2. The second alignment step (S15) and the mounting step (S16) are repeated for each circuit board 2 until the mounting of the LED chips is completed for all the circuit boards arranged in the carrier board 3. In the conventional manufacturing method in which the substrate 2 is put into the bonding device 4 and the LED chips are mounted, the global alignment is required for each circuit board 2, but in the manufacturing method of the present invention, the global alignment is performed once by using the carrier board 3, so that the manufacturing throughput can be improved.

### Extraction Step

The extraction step (S17) is a step of extracting the carrier board 3 from the mounting stage 43 of the bonding device 4 while holding the plurality of circuit boards 2 on which the LED chips are mounted. Since the plurality of circuit boards 2 on which the LED chips are mounted can be collectively extracted from the bonding device 4, the manufacturing throughput can be improved.

Further, it is understood that, even if the advantageous effect is different from those provided by each of the above-described embodiments, the advantageous effect obvious from the description in the specification or easily predicted by persons ordinarily skilled in the art is apparently derived from the present invention.

What is claimed is:

1. A method for manufacturing an LED display, the method comprising:
a dicing step for dicing a plurality of circuit boards from a multi-sided board having the plurality of circuit boards formed within its surface;
a first arrangement step for arranging the plurality of circuit boards on a carrier board;
a second arrangement step for arranging the carrier board on a mounting stage; and
a mounting step for mounting a plurality of LED chips on the plurality of circuit boards on the mounting stage.

2. The method of claim 1, wherein the carrier board is smaller than the multi-sided board.

3. The method of claim 2, wherein the first arrangement step is to periodically arrange the plurality of circuit boards on the carrier board.

4. The method of claim 3, wherein the carrier board has a first alignment mark, and
the method further comprising, after the second arrangement step and before the mounting step, a first alignment step for aligning the LED chips with respect to the carrier board using the first alignment mark.

5. The method of claim 4, wherein each of the plurality of circuit boards has a second alignment mark, and
the method further comprising, after the first alignment step and before the mounting step, a second alignment step for aligning the LED chips with respect to the circuit board using the second alignment mark.
